(19) United States
(12) Patent Application Publication
(10) Pub. No.: US 2015/0351218 A1
(43) Pub. Date: Dec. 3, 2015

(54) COMPONENT BUILT-IN BOARD AND METHOD OF MANUFACTURING THE SAME, AND MOUNTING BODY

(71) Applicant: FUJIKURA LTD., Tokyo (JP)

(72) Inventor: Koji Munakata, Sakura-shi (JP)

(73) Assignee: FUJIKURA LTD., Tokyo (JP)

(21) Appl. No.: 14/685,924

(22) Filed: Apr. 14, 2015

(30) Foreign Application Priority Data
May 27, 2014 (JP) 2014-108874

(51) Int. Cl. H05K 1/02; H05K 1/18; H05K 3/46

(52) U.S. Cl. CPC H05K 1/0206; H05K 3/4623; H05K 3/4697; H05K 1/186

(57) ABSTRACT

A component built-in board comprises a multi-layer structure comprising a plurality of unit boards stacked therein a plurality of electronic components built in thereto in a stacking direction, the plurality of electronic components include a first electronic component, and the plurality of unit boards including: a first board having a first insulating layer and comprising an opening in which the first electronic component is housed; and an intermediate board adjacent to the first board and comprising: a second insulating layer; a first wiring layer formed on a surface on a side of the first board of the second insulating layer; a first adhesive layer provided on at least the side of the first board of the second insulating layer; and a first thermal via that penetrates the first adhesive layer above the first wiring layer and is connected to the first wiring layer, and the first wiring layer of the intermediate board being connected to the first electronic component via the first thermal via.

### CROSS-REFERENCE TO RELATED APPLICATIONS

This application is based upon and claims the benefit of priority from the prior Japanese Patent Application No. 2014-108874, filed on May 27, 2014, the entire contents of which are incorporated herein by reference.

### BACKGROUND OF THE INVENTION

1. Field of the Invention

This invention relates to a component built-in board having an electronic component built in thereto, and a method of manufacturing the same, and to a mounting body.

2. Description of the Prior Art

In order to respond to the demand in recent years for further miniaturization or higher performance levels mainly in compact precision electronic instruments, there has been an increasing need to handle higher levels of integration while advancing miniaturization of electronic components of the likes of semiconductor devices, by component built-in board technology, for example. Known to employ component built-in board technology is the component built-in board disclosed in, for example, Japanese Patent No. 5427305.

This component built-in board has a plurality of unit boards stacked therein and comprises a plurality of electronic components built in thereto, and is configured as follows, namely, having stacked therein in a stacking direction a plurality of double-sided boards that have the electronic component housed in an opening thereof, and having an intermediate board stacked between a plurality of other unit boards including the double-sided boards. As a result, a thickness of a place where the electronic component is housed is reduced, whereby thinning of the component built-in board overall is achieved.

### SUMMARY OF THE INVENTION

In an electronic component configured from a generally employed silicon semiconductor, there is a possibility that when, for example, a Tj temperature (semiconductor element temperature) reaches 175° C. or more, the semiconductor element itself gets destroyed by heat. Therefore, thermal design is performed such that an operational Tj temperature of the electronic component is kept in a range of 80° C. to 100° C., for example.

However, the component built-in board of the conventional technology disclosed in the above-mentioned Japanese Patent No. 5427305 adopts a structure in which a periphery of the electronic component built in thereto is covered by an insulating resin material such as an epoxy resin or polyimide resin having a heat conduction coefficient of approximately about 0.2 W/mk. This insulating resin material shows a heat conduction coefficient of approximately about one thousandth ( 1/1000 times) compared to a metal material such as copper whose heat conduction coefficient is approximately about 370 W/mk. This results in problems that it is difficult for heat of the electronic component to diffuse and that a structural design that takes into account heat dissipation characteristics becomes necessary.

This invention was made in view of the above-mentioned problems and has an object of providing a component built-in board that allows heat of an electronic component built in thereto to be diffused and released while achieving thinning of the component built-in board overall, and a method of manufacturing the component built-in board, and of providing a mounting body.

A component built-in board according to an embodiment of the present invention, the component built-in board being a component built-in board of multi-layer structure comprising a plurality of unit boards stacked therein and a plurality of electronic components built in thereto in a stacking direction, wherein the plurality of electronic components include a first electronic component, and the plurality of unit boards include: a first board having a first insulating layer and comprising an opening in which the first electronic component is housed; and an intermediate board adjacent to the first board and comprising: a second insulating layer; a first wiring layer formed on a surface on a side of the first board of the second insulating layer; a first adhesive layer provided on at least the side of the first board of the second insulating layer; and a first thermal via that penetrates the first adhesive layer above the first wiring layer and is connected to the first wiring layer, and the first wiring layer of the intermediate board is connected to the first electronic component via the first thermal via.

As a result of the component built-in board according to the embodiment of the present invention, a first wiring layer is formed on a surface on a side of a first board of a second insulating layer of an intermediate board disposed adjacently via a first adhesive layer on the first board in which a first electronic component is housed, and a first thermal via connected to the first electronic component and the first wiring layer is formed on the first wiring layer. As a result, the first wiring layer is connected to the first electronic component via the first thermal via, hence heat of the first electronic component can be diffused and released by being conducted to the first wiring layer via the first thermal via. Moreover, the first electronic component is housed in an opening of the first board, hence there is no need to dispose between each of unit boards the likes of an insulator spacer for housing the first electronic component, and thinning of the component built-in board overall can be achieved.

In another embodiment of the component built-in board, the first board includes: a second wiring layer formed on at least one of surfaces of the first insulating layer; and a first inter-layer conductive layer that penetrates the first insulating layer and is connected to the second wiring layer, the intermediate board includes a second inter-layer conductive layer connected to the first wiring layer, and the second inter-layer conductive layer of the intermediate board and the second wiring layer of the first board are connected.

Moreover, in another embodiment of the component built-in board, the first wiring layer is divided into a plurality of first wiring layers such that the first wiring layers are insulated from each other, and at least one second inter-layer conductive layer is connected to each of the divided first wiring layers.

Moreover, in another embodiment of the component built-in board, the plurality of electronic components include a second electronic component, and the plurality of unit boards include a second board that is disposed on an opposite side to the first board of the intermediate board, has a third insulating layer, and comprises an opening in which the second electronic component is housed, the intermediate board includes: a third wiring layer formed on a surface on a side of the second board of the second insulating layer; the first adhesive layer provided on the side of the second board of the second insulating layer; and a second thermal via that penetrates the first adhesive layer above the third wiring layer and is connected to the third wiring layer, and the third wiring layer of the intermediate board is connected to the second electronic component via the second thermal via.

Moreover, in another embodiment of the component built-in board, the second board includes: a fourth wiring layer formed on at least one of surfaces of the third insulating layer; and a third inter-layer conductive layer that penetrates the third insulating layer and is connected to the fourth wiring layer, and the second inter-layer conductive layer of the intermediate board and the fourth wiring layer of the second board are connected.

A method of manufacturing a component built-in board according to an embodiment of the present invention, the component built-in board being a component built-in board of multi-layer structure comprising a plurality of unit boards stacked therein and a plurality of electronic components built in thereto in a stacking direction, comprises the steps of: forming in a first insulating layer an opening in which a first electronic component is to be housed, to produce a first board acting as the unit board; forming a first wiring layer on a surface disposed on a side of the first board of a second insulating layer, and providing a first adhesive layer on at least the side of the first board of the second insulating layer and forming a first thermal via that penetrates the first adhesive layer above the first wiring layer and is connected to the first wiring layer, to produce an intermediate board acting as the unit board; and housing the first electronic component in the opening of the first board, disposing the intermediate board adjacently to the first board via the first adhesive layer, and stacking a plurality of the unit boards in the stacking direction, in the step of stacking, stacking disposing the first board and the intermediate board such that the first wiring layer of the intermediate board is connected to the first electronic component via the first thermal via.

As a result of the method of manufacturing a component built-in board according to the embodiment of the present invention, a first electronic component is housed in an opening of a first board produced as a unit board, an intermediate board having formed therein a first wiring layer and a first thermal via connected to the first wiring layer is disposed adjacently to the first board via a first adhesive layer, and a plurality of the unit boards are stacked in a stacking direction such that the first thermal via of the intermediate board is connected to the first electronic component, whereby the component built-in board is manufactured, hence a component built-in board displaying similar operational advantages to those of the above-described component built-in board can be easily manufactured.

In another embodiment of the method of manufacturing a component built-in board, in the step of producing the first board, a second wiring layer is formed on at least one of surfaces of the first insulating layer, and a first inter-layer conductive layer that penetrates the first insulating layer and is connected to the second wiring layer, is formed, in the step of producing the intermediate board, a second inter-layer conductive layer connected to the first wiring layer, is formed, and in the step of stacking, the first board and the intermediate board are stacked disposed such that the second inter-layer conductive layer of the intermediate board and the second wiring layer of the first board are connected.

Moreover, in another embodiment of the method of manufacturing a component built-in board, in the step of producing the intermediate board, the first wiring layer is formed dividing the first wiring layer into a plurality of first wiring layers such that the first wiring layers are insulated from each other, and the second inter-layer conductive layer is formed such that at least one second inter-layer conductive layer is connected to each of the divided first wiring layers.

Moreover, in another embodiment of the method of manufacturing a component built-in board, the method of manufacturing a component built-in board further comprises the step of: forming in a third insulating layer an opening in which a second electronic component is to be housed, to produce a second board acting as the unit board, in the step of producing the intermediate board, a third wiring layer is formed on a surface disposed on a side of the second board of the second insulating layer, the first adhesive layer is provided on the side of the second board of the second insulating layer, and a second thermal via that penetrates the first adhesive layer above the third wiring layer to be connected to the third wiring layer, is formed, and in the step of stacking, the first board, the intermediate board, and the second board are stacked disposed such that the third wiring layer of the intermediate board is connected to the second electronic component via the second thermal via.

Moreover, in another embodiment of the method of manufacturing a component built-in board, in the step of producing the second board, a fourth wiring layer is formed on at least one of surfaces of the third insulating layer, and a third inter-layer conductive layer that penetrates the third insulating layer and is connected to the fourth wiring layer, is formed, and in the step of stacking, the first board, the intermediate board, and the second board are stacked disposed such that the second inter-layer conductive layer of the intermediate board and the fourth wiring layer of the second board are connected.

Amounting body according to an embodiment of the present invention has another electronic component surface-mounted on at least one mounting surface of a front surface and a back surface of the above-described component built-in board.

### BRIEF DESCRIPTION OF THE DRAWINGS

FIG. 1 is a cross-sectional view showing a component built-in board according to a first embodiment of the present invention.

FIG. 2 is a top view of an intermediate board of the same component built-in board with a part of the intermediate board omitted.

FIG. 3 is a flowchart showing a manufacturing process due to a method of manufacturing the same component built-in board.

FIG. 4 is a flowchart showing a manufacturing process due to the method of manufacturing the same component built-in board.

FIG. 5 is a flowchart showing a manufacturing process due to the method of manufacturing the same component built-in board.

FIG. 6 is a flowchart showing a manufacturing process due to the method of manufacturing the same component built-in board.

FIG. 7A is a cross-sectional view showing the same component built-in board on a manufacturing process basis.

FIG. 7B is a cross-sectional view showing the same component built-in board on a manufacturing process basis.

FIG. 7C is a cross-sectional view showing the same component built-in board on a manufacturing process basis.

FIG. 7D is a cross-sectional view showing the same component built-in board on a manufacturing process basis.

FIG. 7E is a cross-sectional view showing the same component built-in board on a manufacturing process basis.

FIG. 7F is a cross-sectional view showing the same component built-in board on a manufacturing process basis.

FIG. 7G is a cross-sectional view showing the same component built-in board on a manufacturing process basis.

FIG. 8 is a cross-sectional view showing the same component built-in board on a manufacturing process basis.

FIG. 9 is a cross-sectional view showing the same component built-in board on a manufacturing process basis.

FIG. 10 is a cross-sectional view showing a mounting body comprising the component built-in board according to the first embodiment of the present invention.

FIG. 11 is a cross-sectional view showing a component built-in board according to a second embodiment of the present invention.

FIG. 12 is a top view of an intermediate board of the same component built-in board with a part of the intermediate board omitted.

FIG. 13 is a cross-sectional view showing a component built-in board according to a third embodiment of the present invention.

FIG. 14 is a cross-sectional view showing a component built-in board according to a fourth embodiment of the present invention.

FIG. 15 is a top view of an intermediate board of the same component built-in board with a part of the intermediate board omitted.

FIG. 16 is a cross-sectional view showing a component built-in board according to a fifth embodiment of the present invention.

FIG. 17 is a top view of an intermediate board of the same component built-in board with a part of the intermediate board omitted.

FIG. 18 is a cross-sectional view showing a component built-in board according to a sixth embodiment of the present invention.

FIG. 19 is a top view of an intermediate board of the same component built-in board with a part of the intermediate board omitted.

FIG. 20 is a cross-sectional view showing a component built-in board according to a seventh embodiment of the present invention.

FIG. 21 is a top view of an intermediate board of the same component built-in board with a part of the intermediate board omitted.

The accompanying drawings, which are incorporated in and constitute a part of the specification, illustrate embodiments of the invention, and together with the general description given above and the detailed description of the embodiments given below, serve to explain the principles of the invention.

### DESCRIPTION OF THE PREFERRED EMBODIMENTS

A component built-in board and method of manufacturing the same and a mounting body according to embodiments of this invention will be described in detail below with reference to the accompanying drawings.

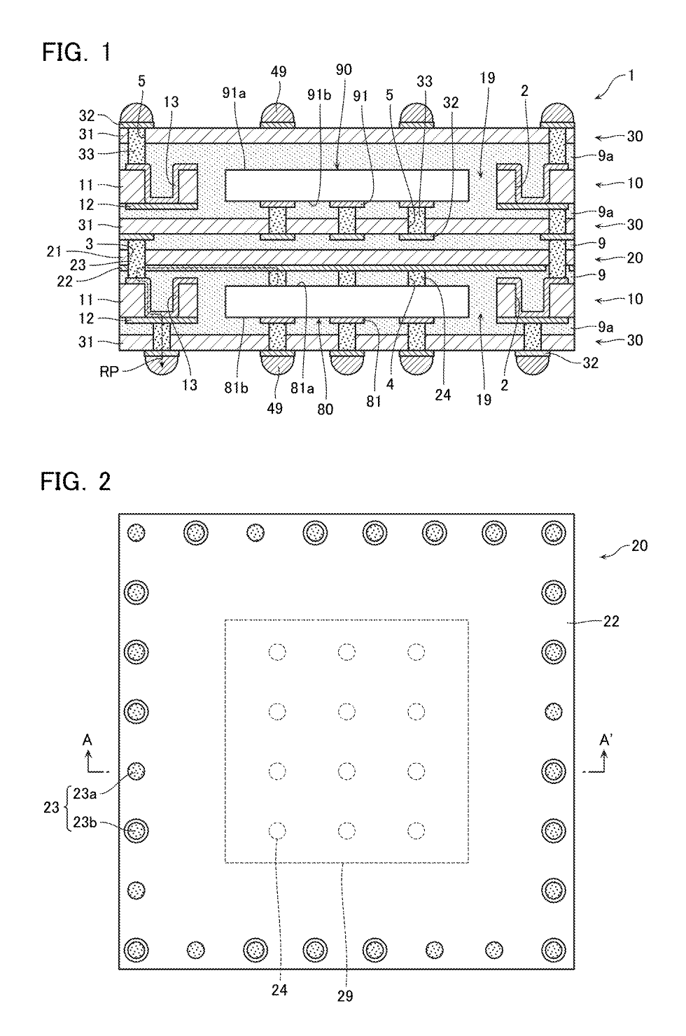

FIG. 1 is a cross-sectional view showing a component built-in board according to a first embodiment of the present invention. FIG. 2 is a top view of an intermediate board of the component built-in board with a part of the intermediate board omitted. Note that FIG. 1 is a view showing a cross-section taken along the line A-A′ in FIG. 2, and FIG. 2 shows the intermediate board with a resin base of the intermediate board omitted. As shown in FIGS. 1 and 2, a component built-in board 1 according to the first embodiment has a plurality of unit boards stacked therein and comprises a plurality of electronic components 80 and 90 built in thereto in a stacking direction.

The component built-in board 1 comprises a structure in which a plurality of double-sided boards 10, an intermediate board 20, and a plurality of single-sided boards 30 acting as the unit boards are stacked collectively by, for example, thermal compression bonding. In this component built-in board 1, the double-sided board 10 disposed on a more downward side in the stacking direction than the intermediate board 20 functions as a first board.

Moreover, the double-sided board 10 disposed on a more upward side in the stacking direction than the intermediate board 20 functions as a second board. Each of the electronic components 80 and 90 is respectively housed in an opening 19 formed in each of the double-sided boards 10, in a state where, for example, sides of back surfaces 81a and 91a are directed to an upward side in the stacking direction and sides of electrode formation surfaces 81b and 91b are directed to a downward side in the stacking direction.

Note that the electronic component 80 housed in the opening 19 of the double-sided board 10 functioning as the first board functions as a first electronic component, and the electronic component 90 housed in the opening 19 of the double-sided board 10 functioning as the second board functions as a second electronic component. The electronic components 80 and 90 built in in the component built-in board 1 are not limited to two as described above, and it is possible for even more to be built in.

Each of the double-sided boards 10 respectively comprises, for example: a film-shaped resin base 11 acting as a first and third insulating layer; and a wiring 12 acting as a second and fourth wiring layer, the wiring 12 being respectively formed on sides of both surfaces of this resin base 11. In addition, each of the double-sided boards 10 comprises, for example, a via 13 acting as a first and third inter-layer conductive layer, the via 13 being formed by plating inside a via hole 2 that penetrates one of the wirings 12 and the resin base 11, the via 13 thereby connecting each of the wirings 12.

Moreover, each of the double-sided boards 10 respectively comprises the opening 19 that has the resin base 11 and the wiring 12 removed at a certain place. The electronic components 80 and 90 are respectively housed in the opening 19. Note that when the first and second boards are not configured by the double-sided board 10, it is sufficient to configure the first and second boards by a single-sided board provided with the opening 19 and having the wiring 12 formed on one side of the resin base 11.

The intermediate board 20 is, for example, adjacent to at least one of the double-sided boards 10 (in FIG. 1, the double-sided board 10 on the downward side) and comprises: a film-shaped resin base 21 acting as a second insulating layer; and a wiring 22 acting as a first and third wiring layer, the wiring 22 being formed on a surface on a side of the double-sided board 10 of the resin base 21. In addition, the intermediate board 20 comprises an adhesive layer 9 acting as a first adhesive layer, the adhesive layer 9 being provided on at least the double-sided board 10 side of the resin base 21 (in FIG. 1, on sides of both surfaces of the resin base 21).

Furthermore, the intermediate board 20 comprises: a via 23 acting as a second inter-layer conductive layer, the via 23 being configured from a conductive paste and being formed by filling the conductive paste inside a via hole 3 that penetrates the adhesive layer 9 and the resin base 21; and a first thermal via 24 configured from the conductive paste and formed by filling the conductive paste inside a via hole 4 that penetrates the adhesive layer 9 above the wiring 22, the first thermal via 24 having one end thereof connected to the wiring 22.

As shown in FIG. 2, the wiring 22 is formed in a solid state along substantially an entire surface on one side of the resin base 21 (the resin base 21 is not illustrated in FIG. 2), including a region 29 overlapping the electronic component 80 in the stacking direction and surrounded by a broken line in FIG. 2. In the present embodiment, the via 23 is configured by: a via 23a which is connected in a surface direction to the wiring 22; and a via 23b which is non-connected.

The via 23a connected to the wiring 22 functions mainly as a heat radiation via, and the via 23b non-connected to the wiring 22 functions as a conductive via for inter-layer signal transmission, for example. Note that hereafter, it is assumed that these vias 23a and 23b, particularly when not clearly indicated, are referred to collectively and notated as the via 23. In the intermediate board 20, the vias 23 are formed in a region somewhat inside of an edge in the surface direction of the resin base 21, with a certain spacing along an outer periphery of the edge.

The first thermal vias 24 are formed in a certain number (here, 3 columns by 4 rows) equally spaced in the region 29, and in addition to respectively having their one ends connected to the wiring 22 as described above, have their other ends connected to the back surface 81a which is a part of the electronic component 80. As a result, the wiring 22 is connected to the electronic component 80 via the first thermal via 24. Note that in the electronic component 80, the part of the electronic component 80 need only be a place where a later-to-be-described re-wiring electrode 81 or circuit (not illustrated) is not formed. Therefore, the part of the electronic component 80 is not limited to the above-described back surface 81a, and may be a side surface, and so on.

As a result, the wiring 22 of the intermediate board 20 functions also as a heat radiation layer that diffuses heat of the electronic component 80 within the layer. This role as a heat radiation layer is similar even assuming that the vias 23 were all non-connected vias 23b. Moreover, the first thermal via 24, the wiring 22, and the via 23 connected to the wiring 22 of the intermediate board 20, together with the wiring 12 and the via 13 of the double-sided board 10 connected to the via 23, or the later-to-be-described via 33, wiring 32, and bump 49 of the single-sided board 30 connected to the wiring 12, configure a heat radiation path RP that passes along an outer peripheral side of the electronic component 80 and is shown by the dotted line arrow in FIG. 1.

Each of the single-sided boards 30 respectively comprises, for example: a film-shaped resin base 31; and a wiring 32 formed on one of surfaces of this resin base 31. In addition, each of the single-sided boards 30 comprises: an adhesive layer 9a provided on a side of the other of the surfaces of the resin base 31; and a via 33 configured from the conductive paste and formed by filling the conductive paste inside a via hole 5 that penetrates this adhesive layer 9a and the resin base 31. Note that the wiring 32 exposed to the outside of the single-sided boards 30 respectively disposed on outermost layer sides of the component built-in board 1 has formed thereon, as desired, the bump 49 configured from solder, for example.

Note that although details will be mentioned later, the double-sided board 10 and the intermediate board 20 can be configured by a double-sided CCL (double-sided copper clad laminated board), and the single-sided board 30 can be configured by a single-sided CCL (single-sided copper clad laminated board). Each of the resin bases 11, 21, and 31 is respectively configured by, for example, a resin film of a low permittivity material and having a thickness of approximately about 12 μm to 25 μm. Employable as the resin film are, for example, a polyimide (PI), a polyolefin (PO), a liquid crystal polymer (LCP), and so on.

The wirings 12, 22, and 32 are configured from, for example, a conductive material such as copper foil pattern formed on the resin bases 11, 21, and 31, and so on. As shown in FIG. 2, the wiring 22 of the intermediate board 20 is formed in a substantially solid state on the resin base 21. The electronic components 80 and 90 built in to the component built-in board 1 are configured from, for example, an active component of a semiconductor element such as a transistor, an integrated circuit (IC), a diode, and so on, or a passive component such as a resistor, a capacitor, a relay, a piezoelectric element, and so on.

The electronic components 80 and 90 shown in FIG. 1 indicate, for example, a WLP (Wafer Level Package) that has been re-wired. Provided on an electrode formation surfaces 81b and 91b side of each of the electronic components 80 and 90 are a plurality of re-wiring electrodes 81 and 91 each formed on a pad not illustrated, and formed in a periphery of these re-wiring electrodes 81 and 91 is an insulating layer not illustrated.

The vias 23 and 33 and the first thermal via 24 are configured from the conductive paste respectively filled into the via holes 3, 5, and 4. The conductive paste includes, for example, at least one kind of metal particle of low electrical resistance selected from the likes of nickel, gold, silver, copper, aluminum, and iron, and at least one kind of metal particle of low melting point selected from the likes of tin, bismuth, indium, and lead. The conductive paste is configured from a paste having mixed into these metal particles a binder component whose main component is an epoxy, an acrylic, a urethane, and so on.

The conductive paste configured in this way comprises metal sintering type characteristics having a curing temperature of approximately 150° C. to 200° C. and a post-curing melting point of approximately 260° C. or more. In addition, the conductive paste comprises characteristics that, for example, the metal of low melting point contained therein can melt and form an alloy at 200° C. or less, and specifically can form an intermetallic compound with the likes of copper or silver. As a result, a connection between each of the vias 23 and 33 and first thermal via 24 and the wirings 12, 22, and 32 is alloyed by an intermetallic compound during thermal compression bonding of collective stacking.

Note that the conductive paste may also be configured by a nanopaste in which, for example, a filler of the likes of gold, silver, copper, and nickel with a nanolevel particle diameter is mixed into a binder component of the above-described kind. In addition, the conductive paste may also be configured by a paste having metal particles of the above-described nickel, and so on, mixed into a binder component of the above-described kind. In this case, the conductive paste is characterized in that electrical connection is performed by contact between fellow metal particles.

Moreover, employable as a method of filling the conductive paste into the via holes 3 to 5 is, for example, a printing method, a spin coating method, a spray coating method, a dispensing method, a laminating method, a method combining use of these methods, and so on. The via 13 is configured by plating applied to the via hole 2 in order to make inter-layer connection between the wirings 12 formed on both surfaces of the resin base 11 as mentioned above.

As shown in FIG. 1, the component built-in board 1 according to the first embodiment has stacked therein six layers of the intermediate board 20, the double-sided board 10, and the single-sided board 30 disposed in that order directed to the downward side in the stacking direction from the intermediate board 20 and including the intermediate board 20, and the single-sided board 30, the double-sided board 10, and the single-sided board 30 disposed in that order directed to the upward side in the stacking direction from the intermediate board 20.

The intermediate board 20 and the double-sided board 10 on its downward side and single-sided board 30 on its upward side are respectively connected by the adhesive layer 9 provided in the intermediate board 20, and each of the double-sided boards 10 and the single-sided boards 30 are respectively connected by the adhesive layer 9a provided in the single-sided board 30. In addition, each of the single-sided boards 30 excluding the single-sided board 30 disposed at an uppermost portion in the stacking direction has some of its vias 33 connected to the re-wiring electrodes 81 and 91 of the electronic components 80 and 90 on an adhesive layer 9a side.

Moreover, each of the single-sided boards 30 has the rest of its vias 33 connected to the wiring 12 or the via 13, and has its wiring 32 disposed in a state of being positioned on an opposite side to a side of the electronic components 80 and 90 of the resin base 31. The adhesive layers 9 and 9a are configured from, for example, an organic system adhesive material including a volatile component, such as an epoxy system or acrylic system, and so on.

In the component built-in board 1 configured in this way, the wiring 22 is formed on a surface on a double-sided board 10 side (downward side) of the resin base 21 of the intermediate board 20 disposed adjacently via the adhesive layer 9 to the double-sided board 10 in which the electronic component 80 is housed, and this wiring 22 has formed thereon the first thermal via 24 connected to the electronic component 80 and the wiring 22.

As a result, the wiring 22 functioning as a heat radiation layer is connected to the back surface 81a of the electronic component 80 via the first thermal via 24, hence it becomes possible for heat of the electronic component 80 to diffuse by being conducted to the wiring 22 via the first thermal via 24 and to be released to the outside via the heat radiation path RP, for example.

In addition, the electronic components 80 and 90 are housed in the opening 19 of the double-sided board 10 to be built in in the stacking direction, hence a thickness of a place where the electronic components 80 and 90 are built in can be adjusted to a thickness substantially equivalent to a thickness of the double-sided board 10, there is no need for the likes of an insulator spacer for housing the electronic components 80 and 90 to be present between each of the unit boards, and thickness of the component built-in board overall can be suppressed to achieve thinning.

Furthermore, after producing the double-sided board 10, the intermediate board 20, and the single-sided board 30 of simple structure and housing the electronic components 80 and 90, the component built-in board 1 can be manufactured by collective stacking by, for example, thermal compression bonding, hence a manufacturing process can be simplified. Note that the electronic components 80 and 90 housed in the opening 19 have their periphery surrounded by the adhesive layers 9 and 9a, and the resin base 21 of the intermediate board 20 intervenes between each of the electronic components 80 and 90 in the stacking direction, hence insulating reliability between the electronic components 80 and 90 can be raised while securing mechanical strength in the stacking direction.

Next, a method of manufacturing the component built-in board 1 according to the first embodiment will be described.

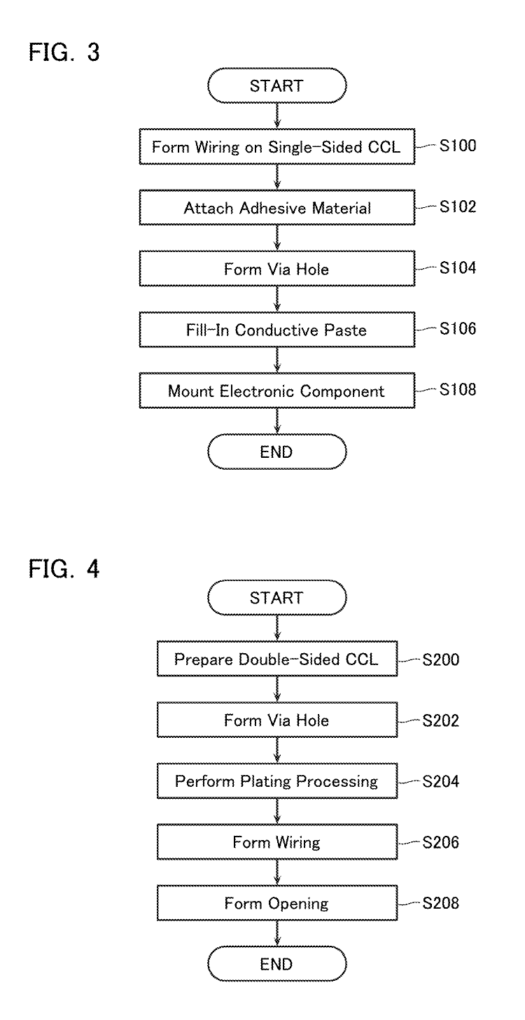

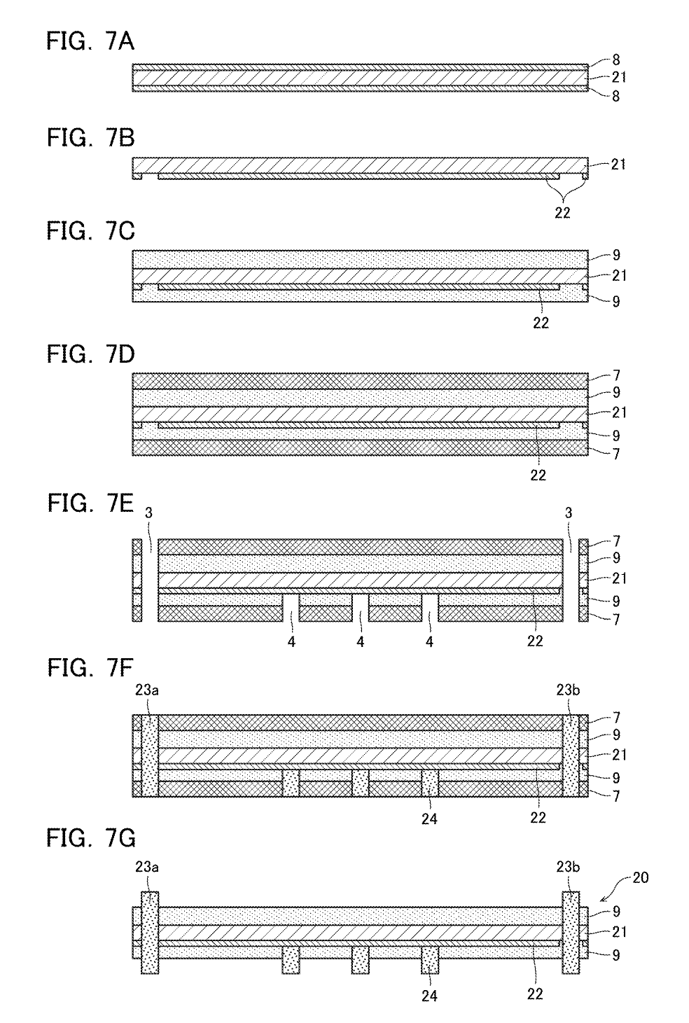

FIGS. 3 to 6 are each a flowchart showing a manufacturing process due to the method of manufacturing a component built-in board. In addition, FIGS. 7A to 9 are each a cross-sectional view showing the component built-in board on a manufacturing process basis. First, the manufacturing process of the single-sided board 30 will be described with reference to FIG. 3.

As shown in FIG. 3, a single-sided CCL in which a conductor layer configured from the likes of a solid-state copper foil is formed on one of surfaces of the resin base 31, is prepared. Then, an etching resist is formed on the conductor of this single-sided CCL by, for example, photolithography, and then etching is performed to pattern form the wiring 32 (step S100).

The wiring 32 may be formed by a publicly known semi-additive method, that is, by a method where, for example, a conductor thin film is formed on the resin base 31 by the likes of vapor deposition or sputtering, and then, after formation of a plating resist by the likes of photolithography, electrolytic plating is performed, and after detachment of the plating resist, the previously formed conductor thin film is removed by etching.

The single-sided CCL employed in this step S100 is, for example, configured from a structure in which the resin base 31 having a thickness of approximately about 25 μm is affixed to the conductor layer configured from copper foil having a thickness of approximately about 12 μm. Employable as this single-sided CCL is, for example, a single-sided CCL produced by applying a varnish of polyimide to copper foil and hardening the varnish, by a publicly known casting method.

Otherwise employable as the single-sided CCL are the likes of a single-sided CCL in which a seed layer is formed on a polyimide film by sputtering and the conductor layer is formed by growing copper by plating, or a single-sided CCL produced by attaching a rolled or electrolytic copper foil and a polyimide film by an adhesive material.

Note that the resin base 31 is not necessarily required to be configured from a polyimide, and as described above, may be configured from a plastic film of a liquid crystal polymer, or the like. Moreover, an etchant whose main component is the likes of ferric chloride or cupric chloride may be employed in the above-described etching.

Next, an adhesive material is attached, by the likes of lamination, to the other of the surfaces on an opposite side to a wiring 32 side of the resin base 31 (step S102), thereby forming the adhesive layer 9a. Employable as the adhesive material attached in this step S102 is, for example, an epoxy system thermosetting film having a thickness of approximately about 25 μm.

An example of the attaching of the adhesive material includes employing a vacuum laminator to, for example, heat-press and attach the adhesive material in a reduced pressure atmosphere, at a temperature where the adhesive material does not harden, by a pressure of 0.3 MPa. Note that the adhesive material employed in the adhesive layers 9 and 9a may be not only the above-described epoxy system thermosetting resin, but also the likes of an acrylic system adhesive material or a thermoplastic adhesive material typified by a thermoplastic polyimide, and so on. Moreover, the adhesive material is not necessarily required to be in a film state, and may have resin coated in a varnish state.

When the adhesive layer 9a has been formed, a laser device such as a UV-YAG laser device, for example, is employed to irradiate laser light from an adhesive layer 9a side toward the wiring 32, whereby the via hole 5 penetrating the adhesive layer 9a and the resin base 31 is formed at a certain place (step S104). After formation of the via hole 5, the inside of the via hole 5 undergoes, for example, plasma desmear processing.

The via hole 5 may otherwise by formed by the likes of a carbon dioxide laser (CO₂ laser) or an excimer laser, or may be formed by the likes of drill processing or chemical etching. Moreover, the desmear processing can be performed by a mixed gas of CF₄ and O₂ (tetrafluoromethane+oxygen), but may also employ another inert gas such as Ar (argon). Furthermore, the desmear processing may be configured as wet desmear processing employing a chemical, rather than so-called dry processing.

When the via hole 5 has been formed, the conductive paste of the above-mentioned kind of configuration is filled into the via hole 5 by a method such as screen printing, for example (step S106), thereby forming the via 33. In this way, a plurality of the single-sided boards 30 each including the resin base 31 on/in which the wiring 32 and the via 33 are formed and provided with the adhesive layer 9a, are manufactured.

Note that the re-wiring electrodes 81 and 91 of the electronic components 80 and 90 separately manufactured as required are aligned with a certain via 33 of the single-sided board 30 using, for example, an electronic component mounting device (mounter) not illustrated. Then, heat is applied at a temperature not exceeding curing temperatures of the adhesive layer 9a of the single-sided board 30 and the conductive paste of the via 33, whereby the electronic components 80 and 90 are provisionally adhered and mounted (step S108). In such a way, a plurality of the single-sided boards 30 and the single-sided boards 30 having the electronic components 80 and 90 mounted thereon, are prepared in advance.

Next, the manufacturing process of the double-sided board 10 will be described with reference to FIG. 4.

First, as shown in FIG. 4, a double-sided CCL in which a conductor layer is formed on both surfaces of the resin base 11 is prepared (step S200), the via hole 2 is formed at a certain place as mentioned above (step S202), and plasma desmear processing, for example, is performed.

Next, panel plate processing is performed on all surfaces of the resin base 11 (step S204) to form a plating layer on the conductor layer and in the via hole 2, and thereby form a prototype of the wiring 12 and the via 13. Then, etching, and so on, is performed on both surfaces of the resin base 11 to pattern form the likes of the wiring 12 or the via 13 (step S206).

Finally, the resin base 11 at a portion thereof where the electronic components 80 and 90 are to be built in is removed by irradiating with laser light using a laser device such as a UV-YAG laser device of the above-mentioned kind to form the opening 19 having a certain opening diameter (step S208), and thereby manufacture a plurality of the double-sided boards 10 each including the opening 19 where the electronic components 80 and 90 are to be housed.

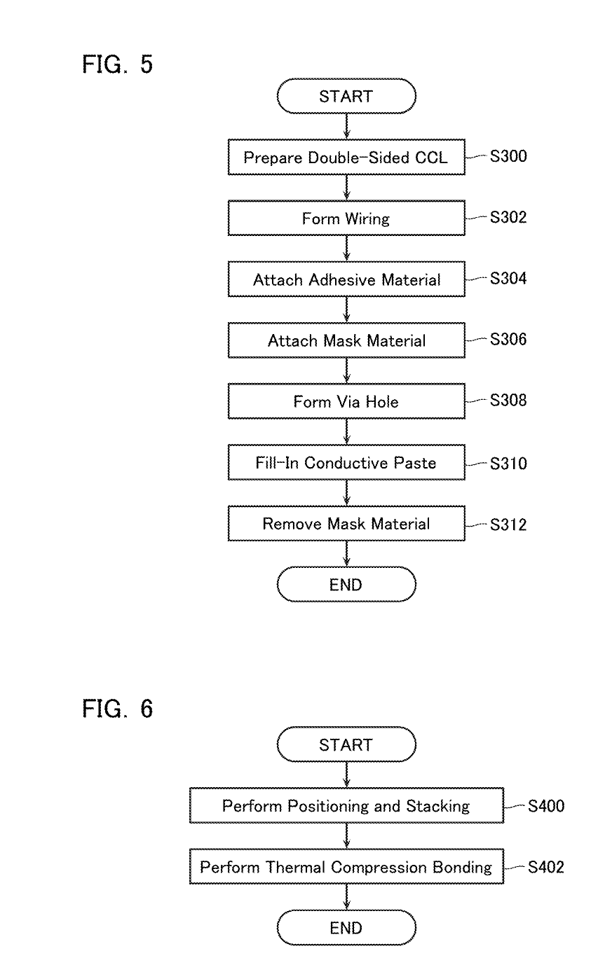

Next, the manufacturing process of the intermediate board 20 will be described with reference to FIG. 5.

First, as shown in FIG. 7A, a double-sided CCL in which a conductor layer 8 is formed on both surfaces of the resin base 21 configured from, for example, a polyimide film, is prepared (step S300). Then, as shown in FIG. 7B, etching, and so on, is performed to remove the conductor layer 8 on one surface and form the wiring 22 on the other surface, for example (step S302).

Next, as shown in FIG. 7C, the adhesive material is attached to sides of both surfaces of the resin base 21, for example (step S304), thereby forming the adhesive layer 9. Then, as shown in FIG. 7D, a mask material 7 is attached to a surface layer of each of the adhesive layers 9 (step S306), and a certain place is irradiated with laser light.

As a result, as shown in FIG. 7E, the via hole 3 penetrating the mask material 7, the adhesive layer 9, and the resin base 21 is formed, and the mask material 7 and adhesive layer 9 above the wiring 22 is penetrated to form the via hole 4 reaching the wiring 22 (step S308). Note that in the above-described step S308, at a place of forming the via 23a later to be connected to the wiring 22, the via hole 3 is formed such that the wiring 22 is exposed inside the via hole 3. On the other hand, at a place of forming the via 23b not to be connected to the wiring 22, the via hole 3 is formed such that the wiring 22 is not exposed inside the via hole 3.

Then, as shown in FIG. 7F, the conductive paste is filled into the formed via holes 3 and 4 (step S310), and finally, as shown in FIG. 7G, the mask material 7 is removed (step S312) to form the via 23 (23a and 23b) and the first thermal via 24. As a result, the intermediate board 20 including the resin base 21 having the adhesive layer 9 provided on sides of both surfaces thereof and having the wiring 22, the via 23, and the first thermal via 24 formed thereon/therein, is manufactured.

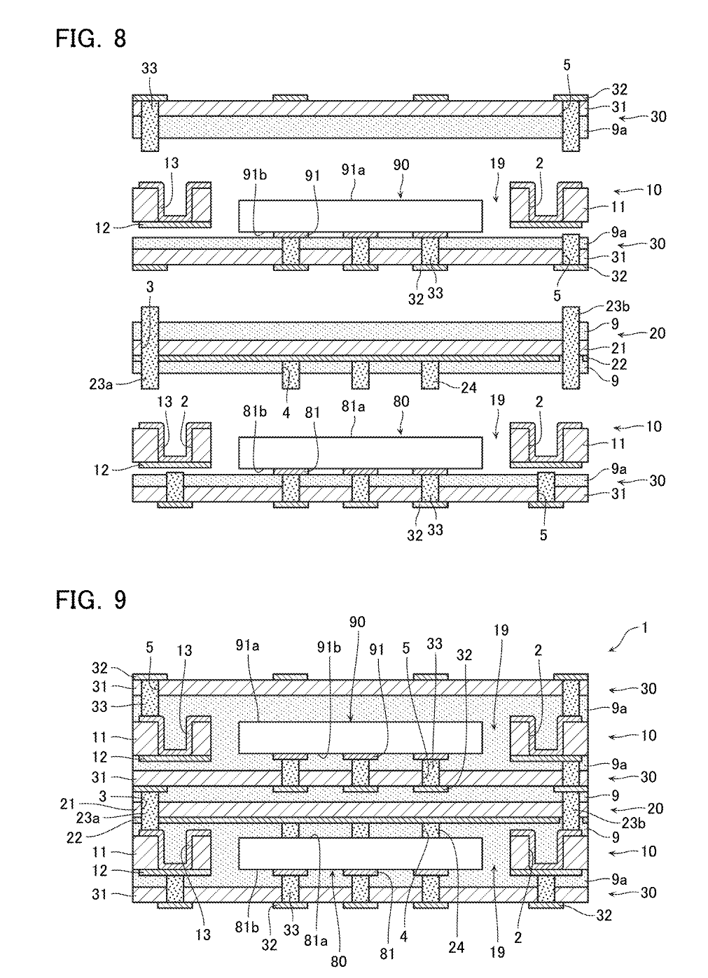

When the plurality of double-sided boards 10, the intermediate board 20, and the plurality of single-sided boards 30 have been produced in this way, then as shown in FIGS. 6 and 8, the double-sided boards 10, the intermediate board 20, and the single-sided boards 30 are positioned and stacked with each of the electronic components 80 and 90 mounted on each of the single-sided boards 30 and the opening 19 of each of the double-sided boards 10 aligned, and with the vias 23a and 23b and first thermal via 24 of the intermediate board 20 and the wiring 12 of the double-sided board 10 or wiring 32 of the single-sided board 30 and the back surface 81a of the electronic component 80 aligned (step S400).

Finally, for example, in the case of performing thermal compression bonding, a vacuum press is employed to collectively stack by thermal compression bonding by applying heat and pressure in a reduced pressure atmosphere of 1 kPa or less (step S402), thereby manufacturing the component built-in board 1 of the kind shown in FIG. 9. By subsequently forming the bump 49 on the wiring 32 in an outermost layer as required, it is possible to manufacture the component built-in board 1 of the kind shown in FIG. 1.

Note that during collective stacking, hardening and alloying of the conductive paste filled into the via holes 3 to 5 are performed simultaneously to hardening of the adhesive layers 9 and 9a between layers or in the opening 19. Moreover, due to an alloy layer of an intermetallic compound, mechanical strength of connections of each of the wirings 12, 22, and 32 or vias 23 and 33 can be increased, and connection reliability can be increased. Stacking processing of each of the boards 10, 20, and 30 is not limited to collective stacking by thermal compression bonding.

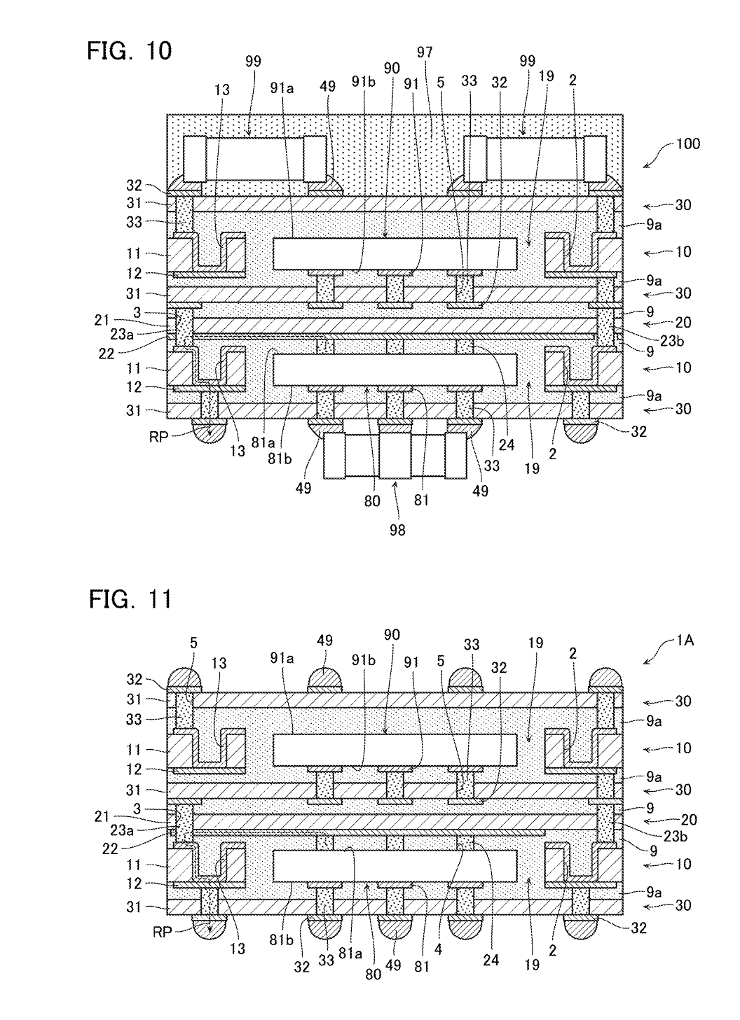

FIG. 10 is a cross-sectional view showing a mounting body comprising the component built-in board according to the first embodiment of the present invention. A mounting body 100 has surface-mounted on a front surface side and a back surface side of the component built-in board 1 according to the first embodiment other electronic components 98 and 99 which are different from the electronic components 80 and 90 built into the component built-in board 1 according to the first embodiment. Each of the surface-mounted electronic components 98 and 99 is connected to the wiring 32 at a certain place of the single-sided board 30 via the bump 49 formed by solder reflow processing at a temperature of approximately about 260° C., for example.

In the illustrated example, the component built-in board 1 has one electronic component 98 surface-mounted on its back surface side and two electronic components 99 surface-mounted on its front surface side, but the two electronic components 99 on the front surface side are further sealed above the wiring 32 by a resin member 97 due to a mold resin, or the like. The mounting body 100 configured in this way can also display similar operational advantages to the operational advantages mentioned above, such as releasing heat of the electronic component 80 built in to the component built-in board 1, via the heat radiation path RP.

Moreover, strain or deformation of the component built-in board 1 overall is suppressed due to interposition of the intermediate board 20, hence surface mounting can be reliably performed. In addition, since solder is not employed in configuration members of the component built-in board 1, high connection reliability can be secured without solder remelting inside the board during solder reflow.

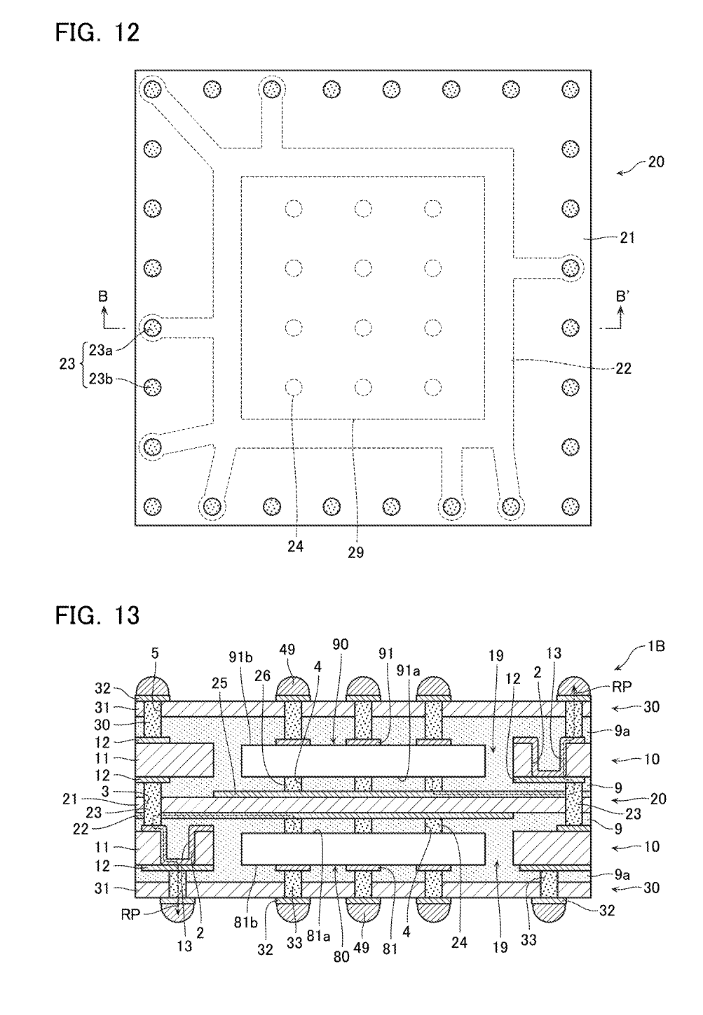

FIG. 11 is a cross-sectional view showing a component built-in board according to a second embodiment of the present invention. FIG. 12 is a top view of an intermediate board of the component built-in board with a part of the intermediate board omitted. Note that FIG. 11 is a view showing a cross-section taken along the line B-B′ in FIG. 12. Moreover, sometimes, hereafter, places duplicating portions already described will be assigned with identical symbols to those already assigned and a description of those places will be omitted.

As shown in FIGS. 11 and 12, a component built-in board 1A according to the second embodiment differs from the component built-in board 1 according to the first embodiment in having the wiring 22 of the intermediate board 20 formed on the resin base 21 not in a substantially solid state, but in a desired pattern. That is, the wiring 22 is formed in a pattern comprising: a rectangular shaped portion covering substantially entirely above the opening 19 including the region 29; and a linear portion extending toward the via 23a.

FIG. 13 is a cross-sectional view showing a component built-in board according to a third embodiment of the present invention. As shown in FIG. 13, a component built-in board 1B according to the third embodiment differs from the component built-in board 1A according to the second embodiment in having a configuration of arrangement of each of the boards on a more upward side in the stacking direction than the intermediate board 20 and a configuration of the intermediate board 20 which are different from those of the component built-in board 1A according to the second embodiment.

That is, the component built-in board 1B has a configuration where the intermediate board 20 includes: a wiring 25 acting as a fifth wiring layer, the wiring 25 being formed on a surface on an opposite side to the wiring 22 of the resin base 21; the adhesive layer 9 provided on a side of this wiring 25; and a second thermal via 26 that penetrates the adhesive layer 9 above the wiring 25 and is connected to the wiring 25.

The via 23 is formed in an arbitrary connection mode and arrangement mode where, for example, a via 23a connected to the wiring 22 when viewed on the one hand from a wiring 22 side functions as a via 23b not connected to the wiring 25 when viewed from a wiring 25 side. Such a component built-in board 1B has the wirings 22 and 25 pattern formed on both surfaces of the resin base 21 of the intermediate board 20, and has the double-sided board 10 and the single-sided board 30 disposed in that order toward the more upward side in the stacking direction than the intermediate board 20.

In addition, the electronic components 80 and 90 housed in the opening 19 of each of the double-sided boards 10 are disposed stacked such that fellow back surfaces 81a and 91a thereof face each other in the stacking direction sandwiching the intermediate board 20, and the back surfaces 81a and 91a are each respectively connected to the first and second thermal vias 24 and 26. Moreover, the fact that the single-sided board 30 that was disposed in an outermost layer of the component built-in board 1A is omitted by such a configuration is different from the component built-in board 1A according to the second embodiment.

Stacking arrangement modes of each of the boards 10, 20, and 30, directed from the upward side to the downward side or from the downward side to the upward side in the stacking direction, are each configured as the single-sided board 30, the double-sided board 10, the intermediate board 20, the double-sided board 10, and the single-sided board 30. Moreover, as well as there being formed the above-mentioned heat radiation path RP of the electronic component 80, there is also formed for the electronic component 90 a heat radiation path RP that passes along an outer peripheral side of the electronic component 90 and is shown by the dotted line arrow in FIG. 13, of the likes of the second thermal via 26, the wiring 25, the via 23, the wiring 12, the via 13, the wiring 12, the via 33, the wiring 32, and the bump 49, for example. This makes it possible to configure the component built-in board 1B of five-layer structure whose heat radiation characteristics are improved while having a plurality of electronic components 80 and 90 built in thereto.

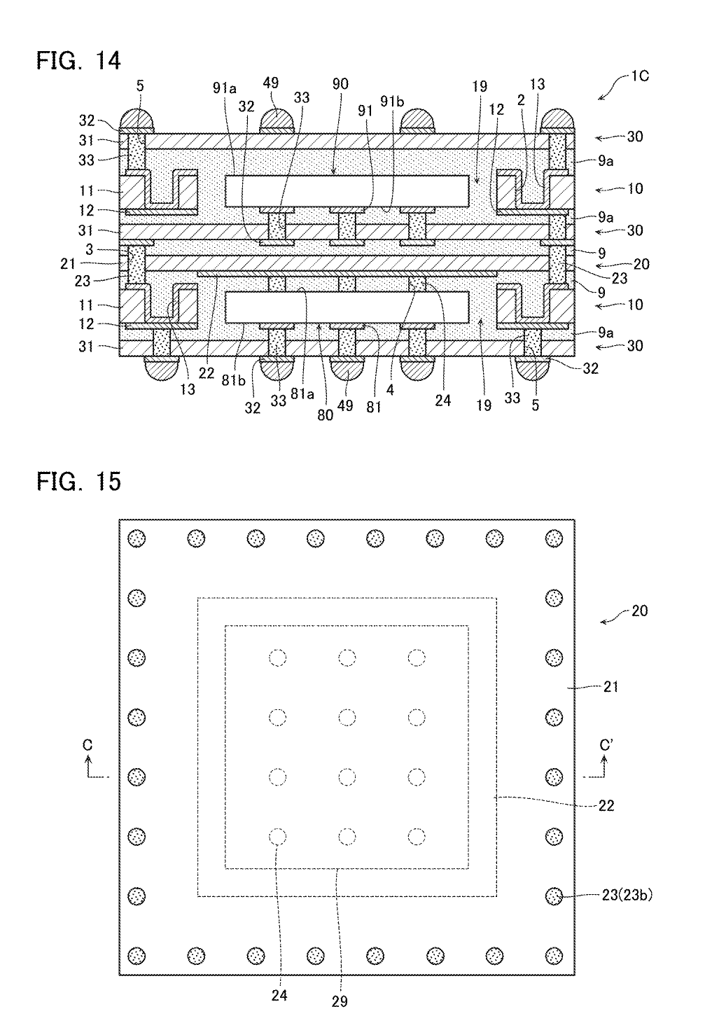

FIG. 14 is a cross-sectional view showing a component built-in board according to a fourth embodiment of the present invention. FIG. 15 is a top view of an intermediate board of the component built-in board with a part of the intermediate board omitted. Note that FIG. 14 is a view showing a cross-section taken along the line C-C′ in FIG. 15. As shown in FIGS. 14 and 15, a component built-in board 1C according to the fourth embodiment differs from the component built-in board 1A according to the second embodiment in having the wiring 22 of the intermediate board 20 formed on the resin base 21 not in a substantially solid state, but in a rectangular shape covering substantially entirely above the opening 19 including the region 29, and, furthermore, in having the vias 23 all configured by the via 23b not connected to the wiring 22.

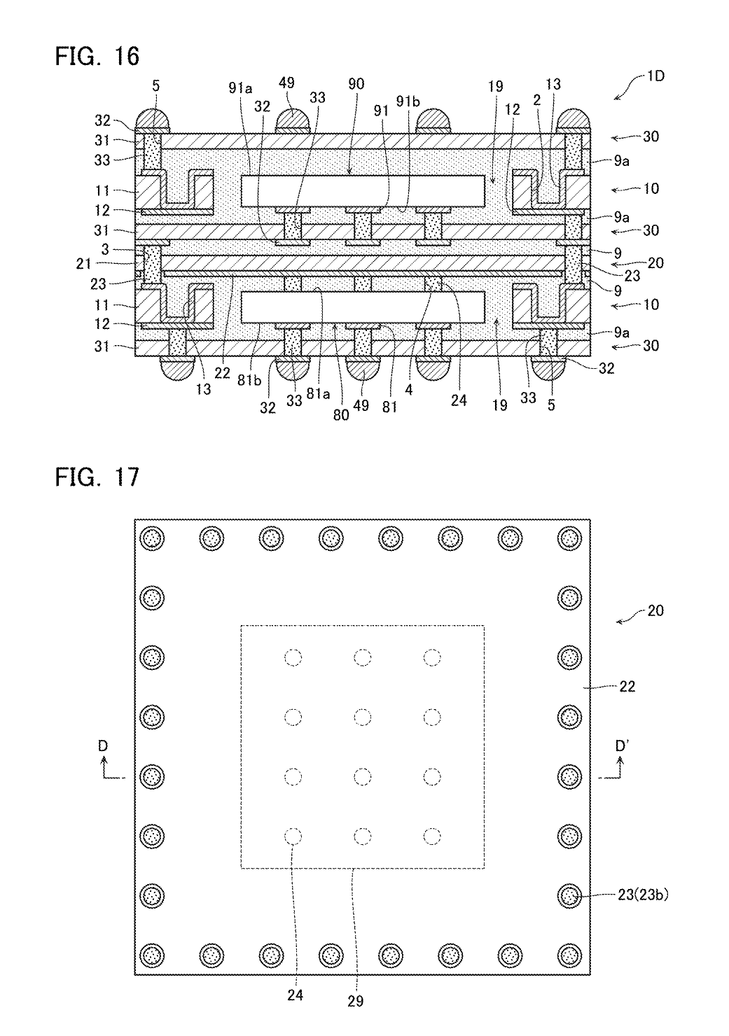

FIG. 16 is a cross-sectional view showing a component built-in board according to a fifth embodiment of the present invention. FIG. 17 is a top view of an intermediate board of the component built-in board with a part of the intermediate board omitted. Note that FIG. 16 is a view showing a cross-section taken along the line D-D′ in FIG. 17, and FIG. 17 shows the intermediate board with a resin base of the intermediate board omitted. As shown in FIGS. 16 and 17, a component built-in board 1D according to the fifth embodiment differs from the component built-in board 1 according to the first embodiment in having the wiring 22 of the intermediate board 20 formed in a substantially solid state on the resin base 21 and in having the vias 23 all configured by the via 23b not connected to the wiring 22.

Note that since the above-mentioned component built-in boards 1C and 1D according to the fourth and fifth embodiments do not have the wiring 22 of the intermediate board 20 in the component built-in boards 1C and 1D connected to the via 23 (that is, the via 23a connected to the wiring 22 does not exist), the above-mentioned heat radiation path RP is not formed. However, since the wiring 22 has an area covering at least above the opening 19, heat of the electronic component 80 can be conducted to the wiring 22 via the first thermal via 24 to be diffused and released within the layer.

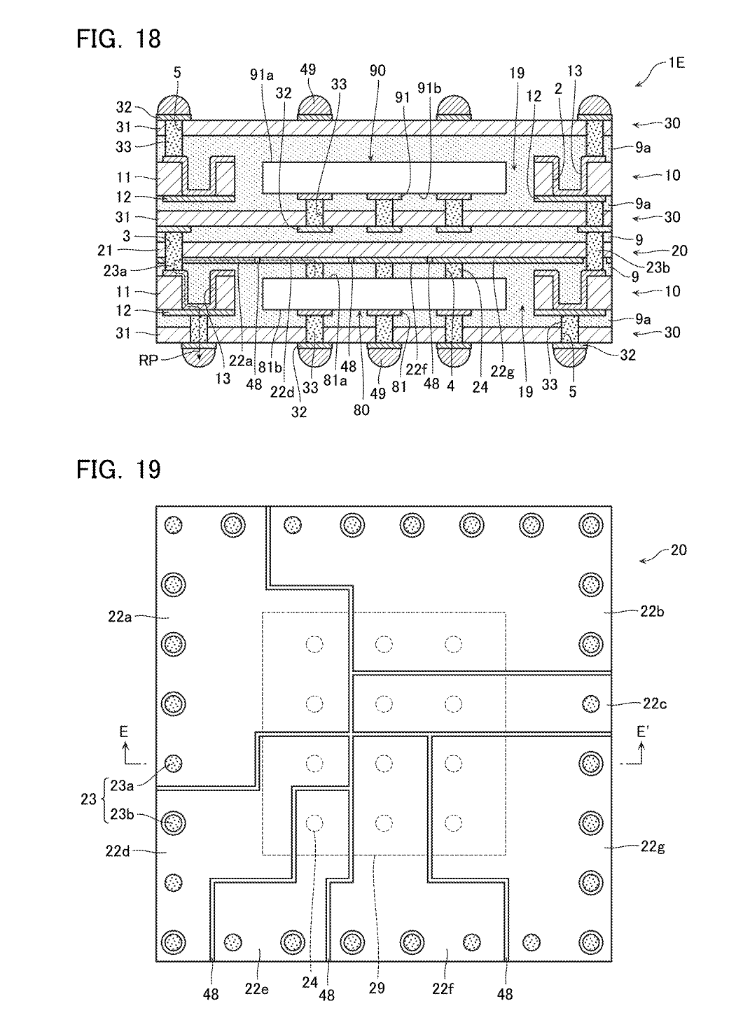

FIG. 18 is a cross-sectional view showing a component built-in board according to a sixth embodiment of the present invention. FIG. 19 is a top view of an intermediate board of the component built-in board with a part of the intermediate board omitted. Note that FIG. 18 is a view showing a cross-section taken along the line E-E′ in FIG. 19, and FIG. 19 shows the intermediate board with a resin base of the intermediate board omitted. As shown in FIGS. 18 and 19, a component built-in board 1E according to the sixth embodiment differs from the component built-in board 1 according to the first embodiment in having the wiring 22 which is formed in a substantially solid state on the resin base 21 of the intermediate board 20 formed in a pattern divided into a plurality of regions of wirings 22a, 22b, 22c, 22d, 22e, 22f, and 22g that are insulated from each other by a slit 48, for example.

Area of each of the wirings 22a to 22g or a pattern of division by the slit 48 are set arbitrarily such that each of the wirings 22a to 22g satisfies desired heat radiation characteristics with respect to heat generated from the electronic component 80, based on heat radiation design via the first thermal via 24 and the wiring 22. Moreover, since each of the wirings 22a to 22g necessarily has the first thermal via 24 and at least one via 23a connected thereto as shown in FIG. 19, the heat radiation path RP of the above-mentioned kind is formed in each of the wirings 22a to 22g.

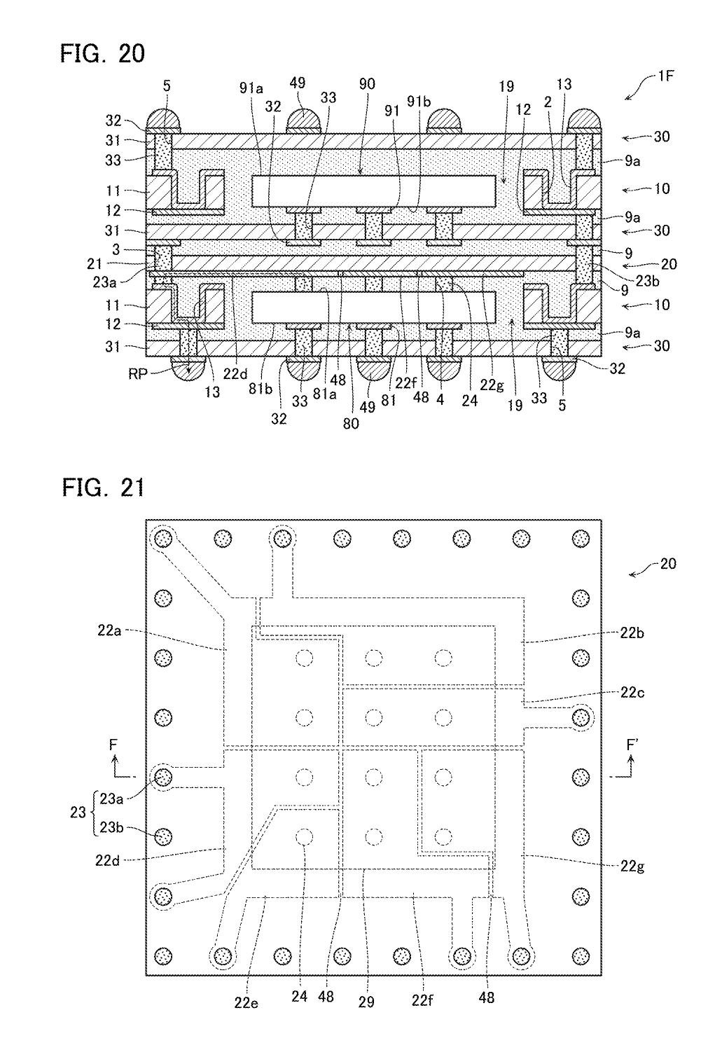

FIG. 20 is a cross-sectional view showing a component built-in board according to a seventh embodiment of the present invention. FIG. 21 is a top view of an intermediate board of the component built-in board with a part of the intermediate board omitted. Note that FIG. 20 is a view showing a cross-section taken along the line F-F′ in FIG. 21. As shown in FIGS. 20 and 21, a component built-in board 1F according to the seventh embodiment is similar to the component built-in board 1A according to the second embodiment in having the wiring 22 of the intermediate board 20 comprising, on the resin base 21: a rectangular shaped portion covering substantially entirely above the opening 19 including the region 29; and a linear portion extending toward the via 23a.

However, the fact that the wiring 22 of the rectangular shaped portion is formed in a pattern divided into a plurality of regions of wirings 22a, 22b, 22c, 22d, 22e, 22f, and 22g that are insulated from each other by a slit 48, for example, and that include the linear portion, is different from the component built-in board 1A according to the second embodiment. As a result, the heat radiation path RP of the above-mentioned kind is formed in each of the wirings 22a to 22g, similarly to in the component built-in board 1E according to the sixth embodiment.

In this way, configurations of the component built-in boards 1A to 1F according to these second through seventh embodiments also allow display of similar operational advantages to those of the first embodiment, namely the operational advantages that heat of the electronic component built in to the inside of the boards can be diffused and released, and overall thinning of the component built-in board manufactured by a simple manufacturing process can be achieved.

While certain embodiments have been described, these embodiments have been presented by way of example only, and are not intended to limit the scope of the inventions. Indeed, the novel methods and device described herein may be embodied in a variety of other forms: furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A component built-in board of multi-layer structure comprising a plurality of unit boards stacked therein and a plurality of electronic components built in thereto in a stacking direction, wherein
the plurality of electronic components include a first electronic component, and
the plurality of unit boards include:
a first board having a first insulating layer and comprising an opening in which the first electronic component is housed; and
an intermediate board adjacent to the first board and comprising: a second insulating layer; a first wiring layer formed on a surface on a side of the first board of the second insulating layer; a first adhesive layer provided on at least the side of the first board of the second insulating layer; and a first thermal via that penetrates the first adhesive layer above the first wiring layer and is connected to the first wiring layer, and
the first wiring layer of the intermediate board is connected to the first electronic component via the first thermal via.

2. The component built-in board according to claim 1, wherein
the first board includes: a second wiring layer formed on at least one of surfaces of the first insulating layer; and a first inter-layer conductive layer that penetrates the first insulating layer and is connected to the second wiring layer,
the intermediate board includes a second inter-layer conductive layer connected to the first wiring layer, and
the second inter-layer conductive layer of the intermediate board and the second wiring layer of the first board are connected.

3. The component built-in board according to claim 2, wherein
the first wiring layer is divided into a plurality of first wiring layers such that the first wiring layers are insulated from each other, and at least one second inter-layer conductive layer is connected to each of the divided first wiring layers.

4. The component built-in board according to claim 1, wherein
the plurality of electronic components include a second electronic component, and
the plurality of unit boards include a second board that is disposed on an opposite side to the first board of the intermediate board, has a third insulating layer, and comprises an opening in which the second electronic component is housed,
the intermediate board includes: a third wiring layer formed on a surface on a side of the second board of the second insulating layer; the first adhesive layer provided on the side of the second board of the second insulating layer; and a second thermal via that penetrates the first adhesive layer above the third wiring layer and is connected to the third wiring layer, and
the third wiring layer of the intermediate board is connected to the second electronic component via the second thermal via.

5. The component built-in board according to claim 4, wherein
the second board includes: a fourth wiring layer formed on at least one of surfaces of the third insulating layer; and a third inter-layer conductive layer that penetrates the third insulating layer and is connected to the fourth wiring layer, and
the second inter-layer conductive layer of the intermediate board and the fourth wiring layer of the second board are connected.

6. A method of manufacturing a component built-in board, the component built-in board being a component built-in board of multi-layer structure comprising a plurality of unit boards stacked therein and a plurality of electronic components built in thereto in a stacking direction, the method comprising the steps of:
forming in a first insulating layer an opening in which a first electronic component is to be housed, to produce a first board acting as the unit board;
forming a first wiring layer on a surface disposed on a side of the first board of a second insulating layer, and providing a first adhesive layer on at least the side of the first board of the second insulating layer and forming a first thermal via that penetrates the first adhesive layer above the first wiring layer and is connected to the first wiring layer, to produce an intermediate board acting as the unit board; and
housing the first electronic component in the opening of the first board, disposing the intermediate board adjacently to the first board via the first adhesive layer, and stacking a plurality of the unit boards in the stacking direction,
in the step of stacking, stacking disposing the first board and the intermediate board such that the first wiring layer of the intermediate board is connected to the first electronic component via the first thermal via.

7. The method of manufacturing a component built-in board according to claim 6, wherein
in the step of producing the first board, a second wiring layer is formed on at least one of surfaces of the first insulating layer, and a first inter-layer conductive layer that penetrates the first insulating layer and is connected to the second wiring layer, is formed,
in the step of producing the intermediate board, a second inter-layer conductive layer connected to the first wiring layer, is formed, and
in the step of stacking, the first board and the intermediate board are stacked disposed such that the second inter-layer conductive layer of the intermediate board and the second wiring layer of the first board are connected.

8. The method of manufacturing a component built-in board according to claim 7, wherein
in the step of producing the intermediate board, the first wiring layer is formed dividing the first wiring layer into a plurality of first wiring layers such that the first wiring layers are insulated from each other, and the second inter-layer conductive layer is formed such that at least one second inter-layer conductive layer is connected to each of the divided first wiring layers.

9. The method of manufacturing a component built-in board according to claim 6, further comprising the step of:
forming in a third insulating layer an opening in which a second electronic component is to be housed, to produce a second board acting as the unit board, wherein
in the step of producing the intermediate board, a third wiring layer is formed on a surface disposed on a side of the second board of the second insulating layer, the first adhesive layer is provided on the side of the second board of the second insulating layer, and a second thermal via that penetrates the first adhesive layer above the third wiring layer to be connected to the third wiring layer, is formed, and
in the step of stacking, the first board, the intermediate board, and the second board are stacked disposed such that the third wiring layer of the intermediate board is connected to the second electronic component via the second thermal via.

10. The method of manufacturing a component built-in board according to claim 9, wherein
in the step of producing the second board, a fourth wiring layer is formed on at least one of surfaces of the third insulating layer, and a third inter-layer conductive layer that penetrates the third insulating layer and is connected to the fourth wiring layer, is formed, and
in the step of stacking, the first board, the intermediate board, and the second board are stacked disposed such that the second inter-layer conductive layer of the intermediate board and the fourth wiring layer of the second board are connected.

11. A mounting body, comprising:
a component built-in board of multi-layer structure comprises a plurality of unit boards stacked therein and a plurality of electronic components built in thereto in a stacking direction; and
another electronic component surface-mounted on at least one mounting surface of a front surface and a back surface of the component built-in board,
the plurality of electronic components include a first electronic component, and
the plurality of unit boards including:
a first board having a first insulating layer and comprising an opening in which the first electronic component is housed; and
an intermediate board adjacent to the first board and comprising: a second insulating layer; a first wiring layer formed on a surface on a side of the first board of the second insulating layer; a first adhesive layer provided on at least the side of the first board of the second insulating layer; and a first thermal via that penetrates the first adhesive layer above the first wiring layer and is connected to the first wiring layer, and
the first wiring layer of the intermediate board being connected to the first electronic component via the first thermal via.

12. The mounting body according to claim 11, wherein
the first board includes: a second wiring layer formed on at least one of surfaces of the first insulating layer; and a first inter-layer conductive layer that penetrates the first insulating layer and is connected to the second wiring layer,
the intermediate board includes a second inter-layer conductive layer connected to the first wiring layer, and
the second inter-layer conductive layer of the intermediate board and the second wiring layer of the first board are connected.

13. The mounting body according to claim 12, wherein
the first wiring layer is divided into a plurality of first wiring layers such that the first wiring layers are insulated from each other, and at least one second inter-layer conductive layer is connected to each of the divided first wiring layers.

14. The mounting body according to claim 11, wherein
the plurality of electronic components include a second electronic component, and
the plurality of unit boards include a second board that is disposed on an opposite side to the first board of the intermediate board, has a third insulating layer, and comprises an opening in which the second electronic component is housed,
the intermediate board includes: a third wiring layer formed on a surface on a side of the second board of the second insulating layer; the first adhesive layer provided on the side of the second board of the second insulating layer; and a second thermal via that penetrates the first adhesive layer above the third wiring layer and is connected to the third wiring layer, and
the third wiring layer of the intermediate board is connected to the second electronic component via the second thermal via.

15. The mounting body according to claim 14, wherein
the second board includes: a fourth wiring layer formed on at least one of surfaces of the third insulating layer; and a third inter-layer conductive layer that penetrates the third insulating layer and is connected to the fourth wiring layer, and
the second inter-layer conductive layer of the intermediate board and the fourth wiring layer of the second board are connected.
